(19) United States
(12) Patent Application Publication
(10) Pub. No.: US 2026/0237358 A1
(43) Pub. Date: Aug. 13, 2026

(54) DISPLAY DEVICE

(71) Applicant: LG Display Co., Ltd., Seoul (KR)

(72) Inventor: SangHyun LIM, Seoul (KR)

(73) Assignee: LG Display Co., Ltd., Seoul (KR)

(21) Appl. No.: 19/532,750

(22) Filed: Feb. 6, 2026

(30) Foreign Application Priority Data
Feb. 10, 2025 (KR) 10-2025-0016693

(51) Int. Cl. G09G 3/3266

(52) U.S. Cl. CPC G09G 3/3266; G09G 2300/0408; G09G 2300/0426

(57) ABSTRACT

A display device includes a substrate having a display area including a plurality of pixels and a non-display area adjacent to the display area. A gate driver is disposed in the display area on the substrate and is configured to supply a gate signal. A plurality of pixel circuits is disposed in the plurality of pixels on the gate driver and is connected to the gate driver. The gate driver includes first transistors, and the pixel circuits include second transistors disposed above the first transistors. Active layers of the first transistors and the second transistors are formed of different materials. Gate lines transmit the gate signal from the gate driver to the pixel circuits. By disposing the gate driver within the display area, the non display area is reduced while stable driving of the pixels is maintained.

### CROSS-REFERENCE TO RELATED APPLICATIONS

This application claims the priority of Korean Patent Application No. 10-2025-0016693 filed on February 10, 2025, in the Korean Intellectual Property Office, the disclosure of which is incorporated herein by reference.

### BACKGROUND

### Technical Field

The present disclosure relates to a display device.

### BACKGROUND

### Description of the Related Art

With the development of technologies in modern society, display devices are being used in various ways to provide information to users. Display devices are included in electronic signs that simply transmit visual information in one direction, as well as various electronic devices that require higher technology to check a user's input and provide information in response to the checked input.

Representative display devices include a liquid crystal display (LCD), a field emission display (FED), an electro-wetting display (EWD), and an organic light emitting display (OLED).

Among them, the organic light emitting display device is a self-luminous display device, and unlike a liquid crystal display device, a separate light source is not required, so that it can be manufactured lightly and thinly. In addition, the organic light emitting display device is advantageous not only in terms of power consumption due to low voltage driving, but also in terms of color implementation, response speed, viewing angle, contrast ratio (CR), so it is expected to be utilized in various fields.

### BRIEF SUMMARY

The disclosed display device places the gate driver within the display area and arranges the pixel circuits above the gate driver, rather than confining the gate driver to a peripheral non display region. By supplying gate signals to the pixel circuits through vertically connected gate lines, this structure reduces the area required outside the display area and enables effective bezel reduction while maintaining normal driving operation of the pixels.

The gate driver and the pixel circuits use different semiconductor materials in a vertically stacked configuration. The gate driver includes transistors having active layers formed of low temperature polysilicon to provide high mobility and stable operation, while the pixel circuits include transistors having active layers formed of oxide semiconductor materials to achieve low leakage current and reliable switching characteristics. This material separation allows each circuit group to be optimized for its electrical function while being integrated within the same display area.

Gate lines are disposed below the pixel circuits so as to overlap the pixel transistors, and a shielding layer is disposed between the gate driver, the gate lines, and the pixel circuits. This arrangement reduces parasitic capacitance and electrical interference caused by vertical overlap and also increases layout flexibility in the pixel circuit layer. As a result, the display device supports high density integration and stable signal transmission while achieving a reduced bezel structure.

Various embodiments of the present disclosure provide a display device capable of minimizing a bezel.

Various embodiments of the present disclosure provide a display device which minimizes a parasitic capacitance between a gate driver and a pixel circuit.

However, the technical benefits of the present disclosure are not limited to the above-mentioned benefits, and other technical benefits may be inferred from the following embodiments.

A display device according to an exemplary embodiment of the present disclosure includes a substrate including a display area including a plurality of pixels and a non-display area surrounding the display area, a gate driver disposed in the display area on the substrate and supplying a gate signal, and a plurality of pixel circuits disposed in the plurality of pixels on the gate driver and connected to the gate driver.

A display device according to another exemplary embodiment of the present disclosure includes a substrate including a display area and a non-display area surrounding the display area, a gate driver disposed on the substrate in the display area and supplying a gate signal, and a plurality of pixel circuits disposed on the gate driver. The gate driver includes a plurality of first transistors including a first active layer, and the plurality of pixel circuits includes a plurality of second transistors including a second active layer made of a material different from that of the first active layer.

According to the present disclosure, a gate driver is disposed in a display area of a display panel to minimize an area of a non-display area outside the display area, thereby minimizing a bezel.

According to the present disclosure, a gate line is disposed under the pixel circuit to overlap the pixel circuit to secure a design margin of the pixel circuit.

According to the present disclosure, a shielding layer is disposed between the pixel circuit and the gate driver to minimize interference between the pixel circuit and the gate driver and a shielding layer is disposed between the gate line and the pixel circuit to minimize parasitic capacitance between the gate line and the pixel circuit.

The effects according to the present disclosure are not limited to the contents exemplified above, and more various effects are included in the present disclosure.

### BRIEF DESCRIPTION OF THE SEVERAL VIEWS OF THE DRAWINGS

The above and other aspects, features and other advantages of the present disclosure will be more clearly understood from the following detailed description taken in conjunction with the accompanying drawings, in which:

FIG. 1 is a block diagram of a display device according to an exemplary embodiment of the present disclosure.

FIG. 2 is a schematic cross-sectional view of a display device according to an exemplary embodiment of the present disclosure.

FIG. 3 is a plan view illustrating a part of a display area of a display device according to an exemplary embodiment of the present disclosure.

FIG. 4 is a cross-sectional view of a pixel of a display device according to an exemplary embodiment of the present disclosure.

FIG. 5 is a plan view illustrating a part of a display area of a display device according to an exemplary embodiment of the present disclosure.

FIG. 6 is a cross-sectional view of a pixel of a display device according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, dimensions (e.g., length, width, height, thickness, radius, diameter, area, etc.), ratios, angles, number of elements, and the like illustrated in the accompanying drawings for describing the embodiments of the present disclosure are merely examples, and the present disclosure is not limited thereto.

A dimension including size and a thickness of each component illustrated in the drawing are illustrated for convenience of description, and the present disclosure is not limited to the size and the thickness of the component illustrated, but it is to be noted that the relative dimensions including the relative size, location, and thickness of the components illustrated in various drawings submitted herewith are part of the present disclosure.

Further, in the following description of the present disclosure, a detailed explanation of known related technologies may be omitted to avoid unnecessarily obscuring the subject matter of the present disclosure. The terms such as “including,” “having,” and “consist of” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When an element or layer is disposed “on” another element or layer, another layer or another element may be interposed directly on the other element or therebetween.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

Like reference numerals generally denote like elements throughout the disclosure.

As used herein, the term "connected" is intended to have the broadest possible meaning. Specifically, the phrase "A is connected to B" encompasses both a direct connection—where no intervening components or elements are present—and an indirect connection, where one or more intermediate components or elements exist between A and B. In other words, "A is connected to B" includes both direct physical or electrical coupling and indirect coupling through one or more intervening components. Unless explicitly stated otherwise, these terms do not require direct physical or electrical contact. The terms "coupled" and "in contact" should be interpreted in the same manner.

The features of various embodiments of the present disclosure can be partially or entirely adhered to or combined with each other and can be interlocked and operated in technically various ways, and the embodiments can be carried out independently of or in association with each other.

Hereinafter, the present disclosure will be described in detail with reference to the drawings.

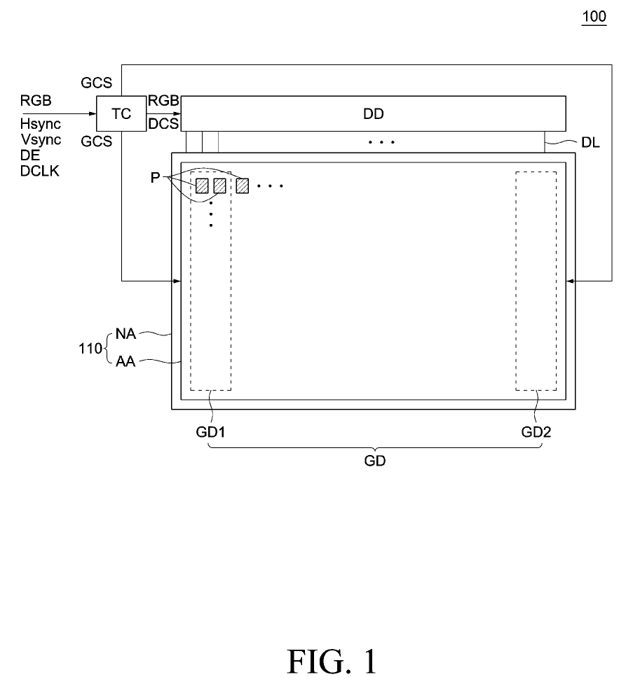

FIG. 1 is a block diagram of a display device according to an exemplary embodiment of the present disclosure.

Referring to FIG. 1, a display device 100 according to an exemplary embodiment of the present disclosure may include a substrate 110, a timing controller TC, a data driver DD, and a gate driver GD.

The substrate 110 may include a display area AA for displaying an image, and a non-display area NA positioned outside the display area AA and in which various signal lines are disposed.

In the active area AA, a plurality of pixels P may be disposed to display an image.

In the active area AA, a plurality of gate lines disposed in a first direction and a plurality of data lines DL disposed in a second direction different from the first direction may be disposed. The plurality of gate lines and the plurality of data lines DL may intersect, and the plurality of pixels P may be disposed in an area where the plurality of gate lines and the plurality of data lines DL intersect. For example, the plurality of pixels P may be disposed in a matrix form.

The plurality of pixels P may be electrically connected to the plurality of gate lines and the plurality of data lines DL. Therefore, a gate signal and a data signal may be applied to each pixel P through the gate line and the data line DL. Each pixel P implements a gray scale by the gate signal and the data signal to display an image in the display area AA.

Each of the plurality of pixels P may be any one of a red pixel, a green pixel, a blue pixel, and a white pixel. The red pixel, the green pixel, the blue pixel, and the white pixel may constitute one unit pixel for color implementation, but the exemplary embodiments of the present disclosure are not limited thereto. The color implemented in the unit pixel may be set according to an emission ratio of the red pixel, the green pixel, the blue pixel, and the white pixel. The white pixel may be omitted in the unit pixel. One data line DL and one gate line may be connected to each of the plurality of pixels P.

The timing controller TC may transmit the input image signal RGB received from the host system to the data driver DD.

The timing controller TC may generate control signals GCS and DCS for controlling operation timings of the gate drivers GD1 and GD2 and the data driver DD by using timing signals such as a clock signal DCLK, a horizontal synchronization signal Hsync, a vertical synchronization signal Vsync, and a data enable signal DE received together with the image data RGB. Here, the horizontal synchronization signal Hsync may be a signal indicating a time taken to display one horizontal line of a screen. The vertical synchronization signal Vsync may be a signal indicating a time taken to display a screen of one frame. The data enable signal DE may be a signal indicating a period of supplying a data signal to the pixel P defined in the substrate 110.

For example, the timing controller TC is applied with a timing signal to output a gate control signal GCS to the gate driver GD and output a data control signal DCS to the data driver DD.

The data driver DD is applied with the data control signal DCS to output a data signal to the data line DL.

For example, the data driver DD generates a sampling signal according to the data control signal DCS, latches the image data RGB according to the sampling signal to be converted into a data signal, and then supplies the data signal to the data line DL in response to a source output enable (SOE) signal.

The data driver DD may be connected to a bonding pad of the substrate 110 in a chip on glass (COG) manner or disposed directly on the substrate 110, or may be integrated and disposed on the substrate 110 in some cases, but the exemplary embodiments of the present disclosure are not limited thereto. Further, the data driver DD may be disposed in a chip on film (COF) manner.

The gate driver GD may generate a scan signal and an emission signal (or an emission control signal) based on the gate control signal GCS.

The gate driver GD may include a scan driver and an emission signal driver. The scan driver generates a scan signal in a row sequential manner to drive at least one scan line connected to each pixel row and may supply the scan signal to the scan lines. The emission signal driver generates an emission signal in a row sequential manner to drive at least one emission signal line connected to each pixel row to supply the emission signal to the emission signal lines.

The gate driver GD may be disposed in the active area AA to supply a gate signal to the gate line. The gate driver GD may include a first gate driver GD1 and a second gate driver GD2.

The first gate driver GD1 may be disposed at one side of the active area AA to supply a gate signal to the gate line, and the second gate driver GD2 may be disposed at the other side of the active area AA to supply a gate signal to the gate line. However, the present disclosure is not limited thereto, and only one gate driver GD may be disposed at one side or the other side of the active area AA to supply a gate signal to the gate line.

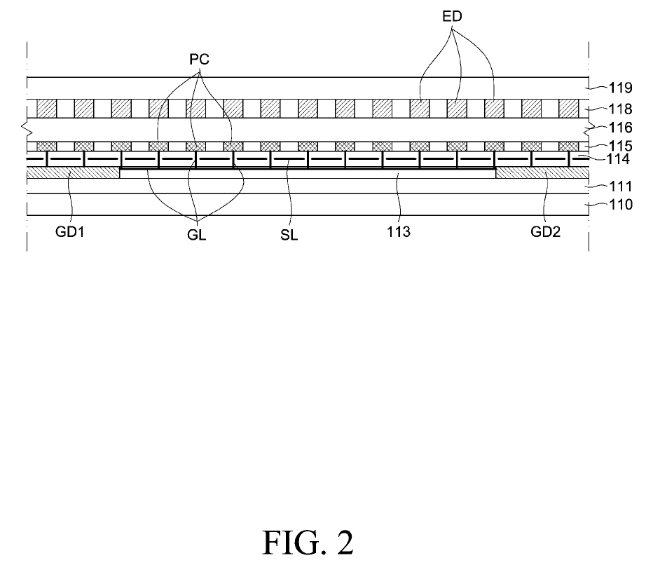

FIG. 2 is a schematic cross-sectional view of a display device according to an exemplary embodiment of the present disclosure. FIG. 2 illustrates schematic positions of a light emitting element ED, a pixel circuit PC, a gate driver GD, a gate line GL, and a shielding layer SL.

Referring to FIG. 2, a display device 100 according to an exemplary embodiment of the present disclosure may include a substrate 110, a lower buffer layer 111, a first gate driver GD1, a second gate driver GD2, a lower insulating layer 113, an upper buffer layer 114, a gate line GL, a shielding layer SL, a pixel circuit PC, an upper insulating layer 115, a planarization layer 116, a light emitting element ED, a bank layer 118, and an encapsulation layer 119.

The substrate 110 may serve to support and protect components of the display device 100 disposed thereon. The substrate 110 may be formed of an insulating material. For example, the substrate 110 may be made of glass, and may be made of a plastic material such as polyimide (PI). However, the present disclosure is not limited thereto.

The lower buffer layer 111 may be disposed on the substrate 110.

The lower buffer layer 111 may minimize diffusion of moisture or oxygen penetrating into the substrate 110 to transistors disposed on the substrate 110. The lower buffer layer 111 may be configured by a single layer of silicon nitride (SiNx) or silicon oxide (SiOx) or a multi-layer thereof, but the exemplary embodiments of the present disclosure are not limited thereto.

The first gate driver GD1 and the second gate driver GD2 may be disposed on the lower buffer layer 111.

The first gate driver GD1 may be disposed at one side of the active area AA to supply a gate signal to the gate line GL, and the second gate driver GD2 may be disposed at the other side of the active area AA to supply a gate signal to the gate line GL.

A lower insulating layer 113 may be disposed on the first gate driver GD1, the second gate driver GD2, and the lower buffer layer 111. The lower insulating layer 113 may be configured by a single layer of silicon nitride (SiNx) or silicon oxide (SiOx) or a multi-layer thereof, but the exemplary embodiments of the present disclosure are not limited thereto.

The upper buffer layer 114 may be disposed on the lower insulating layer 113. The upper buffer layer 114 may be configured by a single layer of silicon nitride (SiNx) or silicon oxide (SiOx) or a multi-layer thereof, but the exemplary embodiments of the present disclosure are not limited thereto.

The shielding layer SL may be disposed between the lower insulating layer 113 and the upper buffer layer 114. The shielding layer SL may shield a configuration disposed above and below the shielding layer SL.

The pixel circuit PC may be disposed on the upper buffer layer 114.

The pixel circuit PC may include a plurality of transistors and capacitors for operating the pixel P.

The upper insulating layer 115 may be disposed on the upper buffer layer 114. The upper insulating layer 115 may be configured by a single layer of silicon nitride (SiNx) or silicon oxide (SiOx) or a multilayer thereof, but the exemplary embodiments of the present disclosure are not limited thereto.

A planarization layer 116 may be disposed on the pixel circuit PC and the upper insulation layer 115. The planarization layer 116 may planarize upper portions of the pixel circuit PC and the upper insulation layer 115. The planarization layer 116 may be formed of an organic material such as acryl resin, epoxy resin, phenolic resin, polyamide resin, or polyimide resin, but the exemplary embodiments of the present disclosure are not limited thereto.

The light emitting element ED and the bank 118 may be disposed on the planarization layer 116.

The light emitting element ED is a component for emitting light and may include an anode, an emission layer, and a cathode.

The bank 118 may define an emission area of the pixel P. In the bank 118, an opening may be disposed so that at least a portion of the anode corresponding to the emission area is exposed. The bank 118 may be made of an inorganic insulating material such as silicon nitride (SiNx) or silicon oxide (SiOx) or an organic insulating material such as benzocyclobutene-based resin, acrylic resin, or imide-based resin, but is not limited thereto.

An encapsulation layer 119 may be disposed on the bank 118. The encapsulation layer 119 may prevent damage to the light emitting element ED due to moisture and impact from the outside. The encapsulation layer 119 may have a multilayer structure.

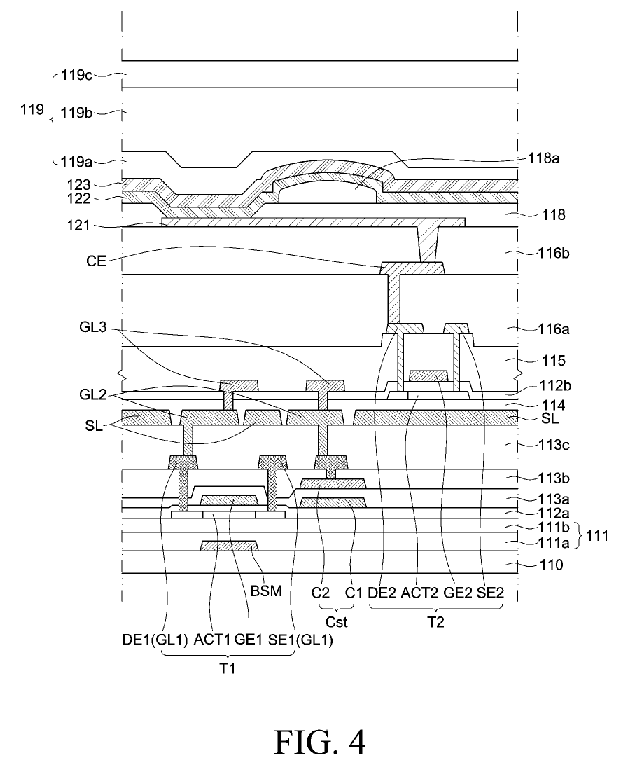

Hereinafter, each configuration of the display device 100 will be described in more detail with reference to FIG. 4.

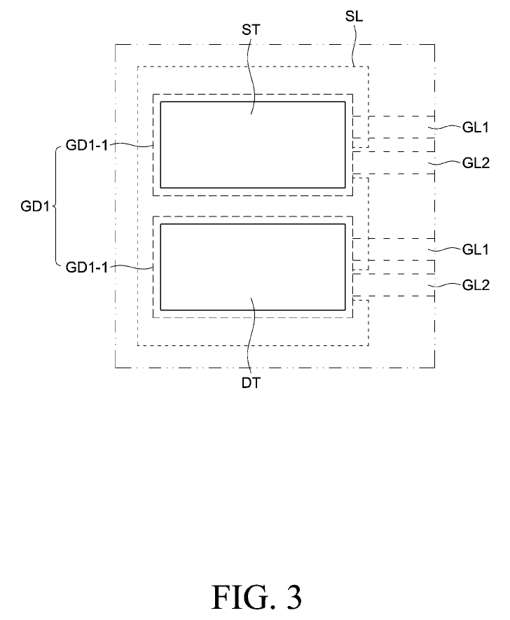

FIG. 3 is a plan view illustrating a part of a display area of a display device according to an exemplary embodiment of the present disclosure. FIG. 4 is a cross-sectional view of a pixel of a display device according to an exemplary embodiment of the present disclosure. FIGS. 3 and 4 illustrate a part of the display area AA in which the first gate driver GD1 is disposed.

Referring to FIGS. 2 and 3, the first gate driver GD1 may include a 1-1-th gate driver GD1-1 and a 1-2-th gate driver GD1-2. A first gate line GL1 and a second gate line GL2 may be connected to each of the 1-1-th gate driver GD1-1 and the 1-2-th gate driver GD1-2.

For example, the 1-1-th gate driver GD1-1 may include a first scan driver and a third scan driver configured to generate a first scan signal and a third scan signal. For example, the 1-1-th gate driver GD1-1 may transmit the generated first scan signal and third scan signal to the pixel address PC through the first gate line GL1 and the second gate line GL2.

For example, the 1-2-th gate driver GD1-2 may include a second scan driver that generates a second scan signal. For example, the 1-2-th gate driver GD1-2 may transmit the generated second scan signal to the pixel address PC through the first gate line GL1 and the second gate line GL2.

Meanwhile, although not illustrated in the drawings, the second gate driver GD2 may include a fourth scan driver configured to generate a fourth scan signal and an emission signal driver configured to generate an emission signal.

The switching transistor region ST and the driving transistor region DT may be disposed to overlap each of the 1-1-th gate driver GD1-1 and the 1-2-th gate driver GD1-2.

For example, a pixel circuit PC including a plurality of transistors and capacitors may be disposed on the 1-1-th gate driver GD1-1 and the 1-2-th gate driver GD1-2. For example, a plurality of switching transistors among a plurality of transistors may be disposed in the switching transistor region ST. For example, a driving transistor and a capacitor among a plurality of transistors may be disposed in the driving transistor region DT.

Referring to FIGS. 2 to 4, in the display device 100 according to the embodiment of the present disclosure, the lower protection metal layer BSM may be disposed on the substrate 110.

The lower protection metal layer BSM may be disposed between the substrate 110 and the lower buffer layer 111 so as to overlap the first transistor T1. Therefore, the lower protection metal layer BSM may be insulated from the first transistor T1.

The lower protective metal layer BSM may be formed of a metal material having a low light transmittance, but the exemplary embodiments of the present disclosure are not limited thereto. The lower protection metal layer BSM may reflect light incident on the first transistor T1 from the bottom of the first transistor T1. The lower protection metal layer BSM may shield light incident on the first transistor T1 and protect the first transistor T1. For example, the lower protection metal layer BSM may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto.

A lower buffer layer 111 may be disposed on the substrate 110 and the lower protection metal layer BSM.

The lower buffer layer 111 may be disposed below the first transistor T1 and delay diffusion of moisture or oxygen introduced into the substrate 110 to the first transistor T1.

The lower buffer layer 111 may include a first lower buffer layer 111a and a second lower buffer layer 111b. The lower buffer layer 111 may be configured as a multilayer including the first lower buffer layer 111a and the second lower buffer layer 111b, but the exemplary embodiments of the present disclosure are not limited thereto. Accordingly, the lower buffer layer 111 may be referred to as a multi-buffer layer. The lower buffer layer 111 may be formed of a single layer or may be formed of a plurality of layers other than two layers, but is not limited thereto.

The first lower buffer layer 111a, for example, may be. It may be formed by a single layer of any one of silicon nitride (SiNx) and silicon oxide (SiOx) or a multi-layer thereof, but is not limited thereto.

For example, the second lower buffer layer 111b may be formed by a single layer of any one of silicon nitride (SiNx) and silicon oxide (SiOx) or a multi-layer thereof, but is not limited thereto.

The first transistor T1 may be disposed on the lower buffer layer 111. The first transistor T1 may be one of a plurality of transistors included in the 1-1-th gate driver GD1-1 and the 1-2-th gate driver GD1-2.

The first transistor T1 may include a first active layer ACT1, a first gate electrode GE1, a first source electrode SE1, and a first drain electrode DE1. However, depending on the design of the pixel circuit, the source electrode may be a drain electrode, and the drain electrode may be a source electrode.

The first active layer ACT1 may be disposed on the lower buffer layer 111. The first active layer ACT1 may include low temperature polycrystalline silicon (LTPS) such as amorphous silicon or polycrystalline silicon.

For example, the first active layer ACT1 may include low-temperature polysilicon (LTPS). The polycrystalline silicon material has a high mobility (100 cm2/Vs or more), low energy power consumption, and excellent reliability, and thus may be applied to a gate driver GD and/or a multiplexer MUX. Therefore, the first active layer ACT1 including the low-temperature polysilicon LTPS may be applied as active layers of the plurality of first transistors T1 included in the first gate driver GD1 and the second gate driver GD2.

For example, the first active layer ACT1 may include a channel region in which a channel is formed when the first transistor T1 is driven, and a first source region and a first drain region on both sides of the channel region. The first source region may be a part of the first active layer ACT1 connected to the first source electrode SE1, and the first drain region may be a part of the first active layer ACT1 connected to the first drain electrode DE1. For example, the first source region and the first drain region may be configured by ion-doping (impurity doping) of the first active layer ACT1. The first source region and the first drain region may be generated by doping ions into the polysilicon material, and the channel region may be a portion that is not ion-doped and remains as the polysilicon material.

The first gate insulating layer 112a may be disposed on the first active layer ACT1. The first gate insulating layer 112a may be configured by a single layer of silicon nitride (SiNx) or silicon oxide (SiOx) or a multi-layer thereof. In the first gate insulating layer 112a, a contact hole through which the first source electrode SE1 and the first drain electrode DE1 of the first transistor T1 are connected to the first source region and the first drain region of the first active layer ACT1 may be formed.

The first gate electrode GE1 of the first transistor T1 may be disposed on the first gate insulating layer 112a.

For example, the first gate electrode GE1 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto. The first gate electrode GE1 may be formed on the first gate insulating layer 112a so as to overlap the channel region of the first active layer ACT1 of the first transistor T1.

The first capacitor electrode C1 of the capacitor Cst may be disposed on the first gate insulating layer 112a. For example, the first capacitor electrode C1 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto.

The first capacitor electrode C1 may be omitted based on the driving characteristics of the display device 100 and the structure and type of the transistor. The first gate electrode GE1 and the first capacitor electrode C1 may be formed by the same process. Further, the first gate electrode GE1 and the first capacitor electrode C1 may be formed of the same material and may be formed on the same layer, but the exemplary embodiments of the present disclosure are not limited thereto.

The lower insulating layer 113 may be disposed on the first gate insulating layer 112a and the first gate electrode GE1. The lower insulating layer 113 may include a first insulating layer 113a, a second insulating layer 113b, and a third insulating layer 113c.

The first insulating layer 113a may be disposed on the first gate insulating layer 112a and the first gate electrode GE1. A contact hole for exposing the first source region and the first drain region of the first active layer ACT1 may be formed in the first insulating layer 113a. For example, the first insulating layer 113a may be configured by a single layer of silicon nitride (SiNx) or silicon oxide (SiOx) or a multi-layer thereof, but the exemplary embodiments of the present disclosure are not limited thereto. The first insulating layer 113a may be an interlayer insulating layer, but the exemplary embodiments of the present disclosure are not limited thereto.

The second capacitor electrode C2 of the capacitor Cst may be disposed on the first insulating layer 113a. The second capacitor electrode C2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof.

The second capacitor electrode C2 may be formed on the first insulating layer 113a so as to overlap the first capacitor electrode C1. In addition, the second capacitor electrode C2 may be formed of the same material as the first capacitor electrode C1, but the exemplary embodiments of the present disclosure are not limited thereto. The second capacitor electrode C2 may be omitted based on the driving characteristics of the display device 100 and the structure and type of the transistor, but is not limited thereto.

The second insulating layer 113b may be disposed on the first insulating layer 113a. A contact hole for exposing the first source region and the first drain region of the first active layer ACT1 may be formed in the second insulating layer 113b, and a contact hole for exposing the second capacitor electrode C2 may be formed. For example, the second insulating layer 113b may be configured by a single layer of silicon nitride (SiNx) or silicon oxide (SiOx) or a multi-layer thereof, but the exemplary embodiments of the present disclosure are not limited thereto.

The first source electrode SE1 and the first drain electrode DE1 of the first transistor T1 may be disposed on the second insulating layer 113b.

The first source electrode SE1 and the first drain electrode DE1 of the first transistor T1 may be electrically connected to the first active layer ACT1 of the first transistor T1 through contact holes of the first gate insulating layer 112a, the first insulating layer 113a, and the second insulating layer 113b.

For example, the first source electrode SE1 and the first drain electrode DE1 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but are not limited thereto.

The first gate line GL1 may be disposed on the second insulating layer 113b.

For example, referring to FIG. 3, the first gate line GL1 may be disposed between the first gate driver GD1 and the second gate driver GD2. The first gate line GL1 extends in a row direction, e. g. , a horizontal direction, of the substrate 110 and may electrically connect the first gate driver GD1 and the second gate driver GD2.

The first gate line GL1 may be formed of the same material on the same layer by the same process as the first source electrode SE1 and the first drain electrode DE1. For example, the first gate line GL1 may be electrically connected to the first source electrode SE1 and the first drain electrode DE1 and may be integrally formed with the first source electrode SE1 and the first drain electrode DE1.

The third insulating layer 113c may be disposed on the first source electrode SE1, the first drain electrode DE1, the first gate line GL1, and the second insulating layer 113b. A contact hole for exposing the first source electrode SE1 and the first drain electrode DE1 may be formed in the third insulating layer 113c. For example, the third insulating layer 113c may be configured by a single layer of silicon nitride (SiNx) or silicon oxide (SiOx) or a multi-layer thereof, but the exemplary embodiments of the present disclosure are not limited thereto.

The second gate line GL2 may be disposed on the third insulating layer 113c. The second gate line GL2 may connect the first gate line GL1 and the pixel circuit PC. The second gate line GL2 may be electrically connected to the first drain electrode DE1 of the first transistor T1 through a contact hole of the third insulating layer 113c.

For example, the second gate line GL2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto.

The shielding layer SL may be disposed on the third insulating layer 113c. The shielding layer SL may be disposed between the gate driver GD and the pixel circuit PC. The shielding layer SL may be disposed between the first transistor T1 and the second transistor T2. For example, referring to FIGS. 2 to 4, the shielding layer SL may be disposed to overlap the pixel circuit PC. For example, the shielding layer SL may be disposed to overlap the switching transistor region ST and the driving transistor region DT. For example, the shielding layer SL may be disposed to overlap the 1-1-th gate driver GD1-1 and the 1-2-th gate driver GD1-2. For example, the shielding layer SL may be disposed to overlap the second transistor T2 constituting the pixel circuit PC. For example, the shielding layer SL may be disposed in an area other than an area in which the second gate line GL2 is disposed. For example, the shielding layer SL may be formed of the same material on the same layer by the same process as the second gate line GL2.

For example, the shielding layer SL is connected to a high potential voltage line which supplies a high potential voltage to the pixel circuit PC or a low potential voltage line which supplies a low potential voltage to the pixel circuit PC to apply a high potential voltage or a low potential voltage.

Therefore, the shielding layer SL is disposed to overlap between the 1-1-th gate driver GD1-1 and the 1-2-th gate driver GD1-2 and the switching transistor area ST and the driving transistor area DT to minimize interference between them. An upper buffer layer 114 may be disposed on the second gate line GL2, the shielding layer SL, and the third insulating layer 113c. For example, the upper buffer layer 114 may be formed by a single layer of any one of silicon nitride (SiNx) and silicon oxide (SiOx) or a multi-layer thereof, but is not limited thereto.

The pixel circuit PC may be disposed on the upper buffer layer 114. The furnace circuit PC may include a plurality of second transistors T2.

The second transistor T2 may include a second active layer ACT2, a second gate electrode GE2, a second source electrode SE2, and a second drain electrode DE2. Depending on the design of the pixel circuit PC, the second source electrode SE2 may be a drain electrode, and the second drain electrode DE2 may be a second source electrode.

The second active layer ACT2 may be disposed on the upper buffer layer 114. The second active layer ACT2 may include an oxide semiconductor material made of a metal oxide such as indium-gallium-zinc-oxide (IGZO), indium-zinc-oxide (IZO), indium-gallium-tin-oxide (IGTO), or indium-gallium-oxide (IGO).

For example, the second active layer ACT2 may be formed of an oxide semiconductor. Since the oxide semiconductor material has a larger band gap than the silicon material, electrons cannot cross the band gap in an off state, and accordingly, the off-current is low. Therefore, the transistor including the active layer made of the oxide semiconductor may be suitable for a switching transistor that maintains the short on-time and the long off-time, but is not limited thereto.

For example, the second active layer ACT2 may include a channel region in which a channel is formed when the second transistor T2 is driven, and a second source region and a second drain region on both sides of the channel region. The second source region may be a portion of the second active layer ACT2 connected to the second source electrode SE2, and the second drain region may be a portion of the second active layer ACT2 connected to the second drain electrode DE2. For example, the second source region and the second drain region may be configured by ion-doping (impurity doping) of the second active layer ACT2. The second source region and the second drain region may be generated by doping ions into the oxide semiconductor material, and the channel region may be a portion in which the ions are not doped, but the oxide semiconductor material remains.

The second gate insulating layer 112b may be disposed on the second active layer ACT2. The second gate insulating layer 112b may be configured by a single layer of silicon nitride (SiNx) or silicon oxide (SiOx) or a multi-layer thereof, but the exemplary embodiments of the present disclosure are not limited thereto. A contact hole through which the second source electrode SE2 and the second drain electrode DE2 of the second transistor T2 are connected to the second source region and the second drain region of the second active layer ACT2 of the second transistor T2 may be formed in the second gate insulating layer 112b.

The second gate electrode GE2 of the second transistor T2 may be disposed on the second gate insulating layer 112b.

For example, the second gate electrode GE2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto. The second gate electrode GE2 may be formed on the second gate insulating layer 112b so as to overlap the channel region of the second active layer ACT2 of the second transistor T2.

The third gate line GL3 may be disposed on the second gate insulating layer 112b.

The third gate line GL3 may connect the second gate line GL2 and the pixel circuit PC. The third gate line GL3 may electrically connect the second gate line GL2 and the second transistor T2. The third gate line GL3 may electrically connect the second gate line GL2 and the second gate electrode GE2 of the second transistor T2. For example, the third gate line GL3 may be electrically connected to the second gate line GL2 through contact holes of the second gate insulating layer 112b and the upper buffer layer 114.

For example, the third gate line GL3 may be formed of the same material on the same layer by the same process as the second gate electrode GE2 of the second transistor T2.

The upper insulation layer 115 may be disposed on the second gate electrode GE2, the third gate line GL3, and the second gate insulation layer 112b. The upper insulating layer 115 may be configured by a single layer of silicon nitride (SiNx) or silicon oxide (SiOx) or a multilayer thereof, but the exemplary embodiments of the present disclosure are not limited thereto. The upper insulating layer 115 may be an interlayer insulating layer, but the exemplary embodiments of the present disclosure are not limited thereto.

The second source electrode SE2 and the second drain electrode DE2 of the second transistor T2 may be disposed on the upper insulation layer 115.

The second source electrode SE2 and the second drain electrode DE2 of the second transistor T2 may be electrically connected to the second active layer ACT2 of the second transistor T2 through the contact hole of the upper insulating layer 115.

For example, the second source electrode SE2 and the second drain electrode DE2 may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but are not limited thereto.

A first planarization layer 116a may be disposed on the second source electrode SE2, the second drain electrode DE2, and the upper insulation layer 115.

The first planarization layer 116a may be an organic layer for planarizing and protecting an upper portion of the second transistor T2. For example, the first planarization layer 116a may be formed of an organic material such as acryl resin, epoxy resin, phenolic resin, polyamide resin, or polyimide resin, but the exemplary embodiments of the present disclosure are not limited thereto.

The connection electrode CE may be disposed on the first planarization layer 116a. The connection electrode CE may be connected to the second drain electrode DE2 of the second transistor T2 through the contact hole of the first planarization layer 116a. Accordingly, the connection electrode CE may be configured to electrically connect the second transistor T2 and the light emitting element ED.

The connection electrode CE may be formed of a single layer or a multi-layer formed of any one of molybdenum (Mo), copper (Cu), titanium (Ti), aluminum (Al), chromium (Cr), gold (Au), nickel (Ni), and neodymium (Nd) or an alloy thereof, but is not limited thereto.

The second planarization layer 116b may be disposed on the first planarization layer 116a and the connection electrode CE. The top surface of the second planarization layer 116b may have a surface parallel to the substrate 110. Accordingly, the second planarization layer 116b may planarize a step that may occur due to the components disposed therebelow. For example, the second planarization layer 116b may be formed of an organic material such as acryl resin, epoxy resin, phenolic resin, polyamide resin, or polyimide resin, but is not limited thereto.

The light emitting element ED may be disposed on the second planarization layer 116b.

The light emitting element ED may include an anode 121, a emission layer 122, and a cathode 123.

The anode 121 may be disposed on the second planarization layer 116b. The anode 121 may be connected to the connection electrode CE through a contact hole of the second planarization layer 116b and may be electrically connected to the second transistor T2. The anode 121 may be formed of a conductive material, but the exemplary embodiments of the present disclosure are not limited thereto.

When the display device 100 is a top emission type in which light emitted from the light emitting element ED is emitted above the substrate 110 on which the light emitting element ED is disposed, the anode 121 may include a reflective layer and a transparent conductive layer disposed on the reflective layer. For example, the transparent conductive layer may be formed of a transparent conductive oxide such as indium tin oxide (ITO) or indium zinc oxide (IZO), but the exemplary embodiments of the present disclosure are not limited thereto. The reflective layer may be formed of silver (Ag), aluminum (Al), gold (Au), molybdenum (Mo), tungsten (W), chromium (Cr), or an alloy thereof, but is not limited thereto.

The bank 118 may be disposed on the second planarization layer 116b and the anode 121. The bank 118 may be disposed while covering an end of the anode 121. A portion of the bank 118 corresponding to the emission area of the sub pixel SP may be opened. A part of the anode 121 may be exposed through the open part of the bank 118 (hereinafter, referred to as an open area). The bank 118 may be made of an inorganic insulating material such as silicon nitride (SiNx) or silicon oxide (SiOx) or an organic insulating material such as benzocyclobutene-based resin, acrylic resin, or imide-based resin, but is not limited thereto. The bank 118 may be made of a material including a black pigment or an organic material such as polyimide resin or a photosensitive polymer, but the exemplary embodiments of the present disclosure are not limited thereto. When the bank 118 is made of a material including a black pigment or a black dye, it may be a black bank. When the bank 118 is formed of a material including a black pigment or a black dye, light from the outside may be blocked or light reflected from the outside may be blocked, thereby further improving the luminance of the display device. A spacer 118a may be further disposed on the bank 118. The spacer 118a may be formed of the same material as the bank 118, but the exemplary embodiments of the present disclosure are not limited thereto.

The emission layer 122 may be disposed on the anode 121 and the bank 118. The emission layer 122 may be disposed in the open area and around the open area of the bank 118. Accordingly, the emission layer 122 may be disposed on the anode 121 exposed through the open area of the bank 118.

The emission layer 122 may include a plurality of organic material layers. For example, the emission layer 122 may include organic material layers such as a hole injection layer, a hole transport layer, an electron transport layer, and an electron injection layer, but the exemplary embodiments of the present disclosure are not limited thereto. When the emission layer 122 is the emission layer 122 which emits white light, the light emitted from the emission layer 122 may be converted into light of various colors by a plurality of color filters, but is not limited thereto.

The cathode 123 may be disposed on the emission layer 122. Since the cathode 123 supplies electrons to the emission layer 122, the cathode 123 may be made of a conductive material having a low work function. The cathode 123 may be formed as one layer over the plurality of sub pixels SP. For example, the cathodes 123 of the plurality of sub pixels SP may be connected to and integrated with each other.

For example, the cathode 123 may be formed of a transparent conductive material such as indium tin oxide (ITO) or indium zinc oxide (IZO) or a ytterbium (Yb) alloy, and may further include a metal doping layer, but is not limited thereto.

An encapsulation layer 119 may be disposed on the light emitting element ED.

The encapsulation layer 119 may have a multilayer structure including a first encapsulation layer 119a, a second encapsulation layer 119b, and a third encapsulation layer 119c, but the exemplary embodiments of the present disclosure are not limited thereto. The encapsulation layer may have a single layer structure, but is not limited thereto.

The first encapsulation layer 119a and the third encapsulation layer 119c may be made of an inorganic material, and the second encapsulation layer 119b may be made of an organic material, but the exemplary embodiments of the present disclosure are not limited thereto. The second encapsulation layer 119b may be thickest among the first encapsulation layer 119a, the second encapsulation layer 119b, and the third encapsulation layer 119c. The second encapsulation layer 119b may planarize an upper portion of the light emitting element ED.

The first encapsulation layer 119a may be disposed on the cathode 123 and most adjacent to the light emitting element ED. The first encapsulation layer 119a may be formed of an inorganic insulating material on which low-temperature deposition may be performed. For example, the first encapsulation layer 119a may be made of silicon nitride (SiNx), silicon oxide (SiOx), silicon oxynitride (SiON), or aluminum oxide (Al2O3), but is not limited thereto.

Since the first encapsulation layer 119a is deposited in a low-temperature atmosphere, it is possible to prevent damage to the emission layer 122 including an organic material vulnerable to a high-temperature atmosphere during the deposition process.

The second encapsulation layer 119b may be disposed on the first encapsulation layer 119a. The second encapsulation layer 119b may be disposed to have a smaller area than the first encapsulation layer 119a. In this case, the second encapsulation layer 119b may be disposed to expose both ends of the first encapsulation layer 119a. The second encapsulation layer 119b may serve as a buffer to alleviate stress between layers due to bending of the display device 100 and to enhance planarization performance.

For example, the second encapsulation layer 119b may be made of an organic insulating material such as acrylic resin, epoxy resin, polyimide, polyethylene, or silicon oxycarbon (SiOC). For example, the second encapsulation layer 119b may be formed by an inkjet method, but is not limited thereto.

The third encapsulation layer 119c may be formed above the substrate 110 on which the second encapsulation layer 119b is formed so as to cover upper surfaces and side surfaces of the second encapsulation layer 119b and the first encapsulation layer 119a. In this case, the third encapsulation layer 119c may minimize or block the permeation of external moisture or oxygen into the first encapsulation layer 119a and the second encapsulation layer 119b. For example, the third encapsulation layer 119c may be made of an inorganic insulating material, such as silicon nitride (SiNx), silicon oxide (SiOx), silicon oxynitride (SiON), or aluminum oxide (Al2O3), but is not limited thereto.

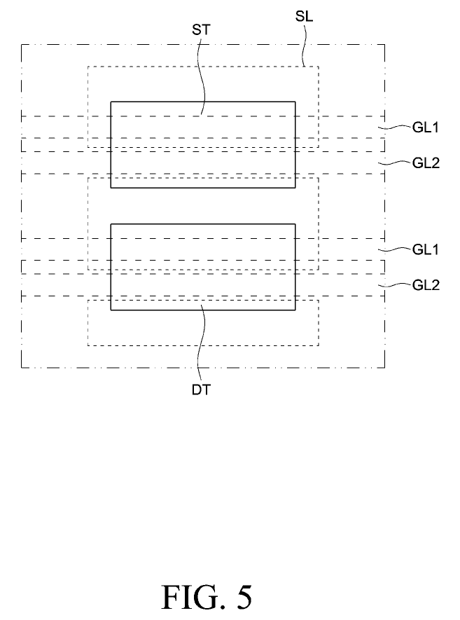

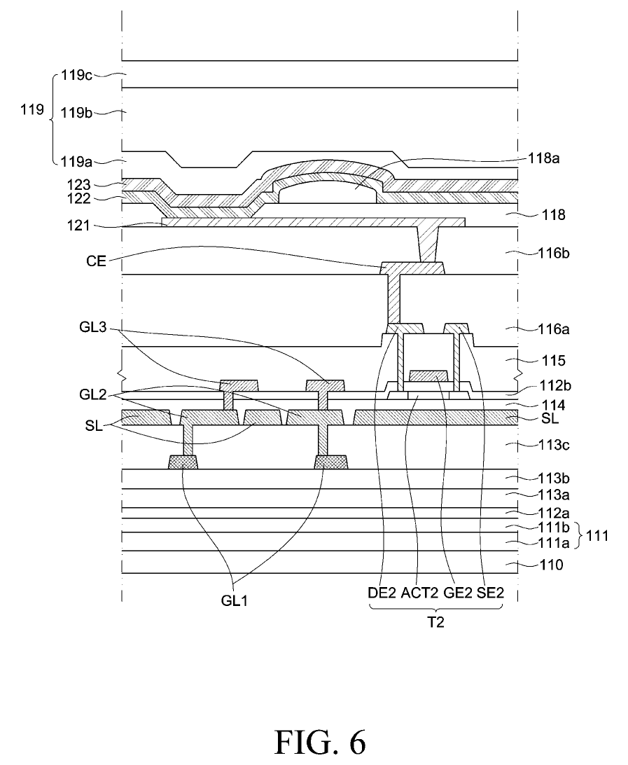

FIG. 5 is a plan view illustrating a part of a display area of a display device according to an exemplary embodiment of the present disclosure. FIG. 6 is a cross-sectional view of a pixel of a display device according to an exemplary embodiment of the present disclosure. FIGS. 5 and 6 illustrate a part of the display area AA in which the gate driver GD is not disposed. In FIGS. 5 and 6, descriptions of redundant components will be omitted in comparison with those in FIGS. 3 and 4, respectively.

Referring to FIGS. 5 and 6, in the active area AA in which the gate driver GD is not disposed, the first gate line GL1 and the second gate line GL2 may extend in the row direction, for example, in the horizontal direction. The pixel circuit PC may be disposed on the first gate line GL1 and the second gate line GL2. The pixel circuit PC may include a plurality of second transistors T2. For example, all the second transistors T2 constituting the pixel circuit PC may be oxide semiconductor transistors including an oxide semiconductor material such as indium-gallium-zinc-oxide (IGZO), indium-zinc-oxide (IZO), indium-gallium-tin-oxide (IGTO), or indium-gallium-oxide (IGO).

The shielding layer SL may be disposed between the gate line GL and the pixel circuit PC disposed below the pixel circuit PC. The shielding layer SL may be disposed to overlap the switching transistor region ST and the driving transistor region DT. For example, the shielding layer SL may be disposed to overlap the second transistor T2. For example, the shielding layer SL may be disposed between the first gate line GL1 and the second transistor T2. For example, the shielding layer SL may be disposed in an area other than an area in which the second gate line GL2 is disposed.

Accordingly, it is possible to minimize the occurrence of parasitic capacitance between the pixel circuit PC and the first gate line GL1 disposed below the pixel circuit PC.

In the display device, an area for disposing the gate driver is inevitably required in the non-display area outside the display area, so there is a limit to reducing the bezel.

Accordingly, in the display device 100 according to the exemplary embodiment of the present disclosure, the gate driver GD is disposed on at least one side of the display area AA on the substrate 110. A pixel circuit PC for driving the pixel P is disposed above the gate driver GD. The pixel circuit PC receives a gate signal from the gate driver GD through a plurality of gate lines GL connected through a contact hole. Accordingly, in the display device 100 according to the exemplary embodiment of the present disclosure, the gate driver GD is disposed in the display area AA of the display panel to minimize the area of the non-display area NA outside the display area AA and minimize the bezel.

In addition, in the display device 100 according to the exemplary embodiment of the present disclosure, the gate line GL is disposed below the pixel circuit PC. The gate line GL is disposed under the second transistor T2 of the pixel circuit PC so as to overlap the second transistor T2. Accordingly, in the display device 100 according to the exemplary embodiment of the present disclosure, the gate line GL is disposed under the pixel circuit PC to minimize the line disposed on the same layer as the pixel circuit PC and secure the design margin of the pixel circuit PC.

Further, in the display device 100 according to the exemplary embodiment of the present disclosure, the shielding layer SL is disposed below the pixel circuit PC. The shielding layer SL is disposed between the gate line GL and the pixel circuit PC disposed below the pixel circuit PC. Accordingly, the display device 100 according to the exemplary embodiment of the present disclosure may minimize the occurrence of parasitic capacitance between the pixel circuit PC and the gate line GL disposed below the pixel circuit PC.

The exemplary embodiments of the present disclosure can also be described as follows:

In an embodiment, a display device includes a substrate having a display area and a non display area adjacent to the display area. A gate driver is disposed on the substrate in the display area. The gate driver includes at least one first transistor T1 having a first active layer ACT1 disposed on the substrate. The first transistor T1 may be configured to generate or supply a gate signal for driving pixel circuits disposed in the display area.

A pixel circuit is disposed in the display area. The pixel circuit includes at least one second transistor T2 having a second active layer ACT2. The pixel circuit is electrically connected to the gate driver so as to receive the gate signal supplied by the gate driver.

As shown in FIG. 4, the first active layer of the first transistor and the second active layer of the second transistor are disposed at different vertical levels with respect to the substrate, with at least one insulating layer interposed therebetween. As a result, the pixel circuit and the gate driver are vertically separated while being electrically connected.

In a plan view of the substrate, the pixel circuit overlaps the gate driver. That is, at least a portion of the pixel circuit is positioned above or below the gate driver when viewed in a direction perpendicular to the substrate.

In an embodiment, the first active layer of the first transistor included in the gate driver includes low temperature polysilicon. The second active layer of the second transistor included in the pixel circuit includes an oxide semiconductor material. By using different semiconductor materials for the first active layer and the second active layer, the electrical characteristics of the gate driver and the pixel circuit may be independently optimized.

In an embodiment, the display device further includes a gate line GL configured to transmit the gate signal from the gate driver to the pixel circuit. The gate line electrically connects the gate driver to the pixel circuit to enable driving of the second transistor.

As shown in FIGS. 4 and 6, the gate line is disposed at a vertical level different from both the first active layer and the second active layer. In some embodiments, the gate line is disposed at a vertical level between the first active layer and the second active layer, such that the gate line is vertically interposed between the gate driver and the pixel circuit.

In a plan view of the substrate, the gate line overlaps the second transistor of the pixel circuit. Accordingly, the gate line may be routed beneath or above the pixel circuit while occupying a reduced planar area.

In an embodiment, the display device further includes a shielding layer SL disposed between the gate driver and the pixel circuit. The shielding layer is configured to reduce electrical interference between the gate driver and the pixel circuit.

In an embodiment, a gate line configured to transmit the gate signal from the gate driver to the pixel circuit is provided, and the shielding layer is disposed between the gate line and the second transistor of the pixel circuit. Accordingly, the shielding layer is vertically interposed between the gate line and the second transistor.

In some embodiments, the shielding layer is disposed on the same layer as the gate line. In other embodiments, the shielding layer and the gate line are formed in the same process step and include the same conductive material. For example, the shielding layer and the gate line may be patterned concurrently from a single conductive layer.

In a plan view of the substrate, the shielding layer overlaps the second transistor of the pixel circuit. As a result, the shielding layer effectively shields the pixel circuit from signals transmitted through the gate line.

In an embodiment, the gate driver is disposed along only one side of the display area. In this configuration, the pixel circuit overlaps the gate driver only along that side of the display area. Other portions of the display area may not include the gate driver beneath the pixel circuits.

In an embodiment, the display area includes a first portion and a second portion. The gate driver is disposed in the first portion of the display area. A pixel circuit disposed in the first portion of the display area overlaps the gate driver in a plan view of the substrate.

As used herein, the display area may include different portions depending on whether a gate driver is disposed therein. In a portion of the display area in which the gate driver is disposed on the substrate (see FIG. 3), pixel circuits disposed in that portion overlap the gate driver in a plan view of the substrate. This portion of the display area may be referred to as a first portion.

In another portion of the display area, the gate driver is not disposed on the substrate (see FIG. 5). Pixel circuits disposed in this portion of the display area therefore do not overlap the gate driver in a plan view of the substrate. This portion of the display area may be referred to as a second portion.

The first portion and the second portion are not required to be separately defined or physically demarcated regions, but are distinguished based on the presence or absence of the gate driver beneath the pixel circuits, as illustrated in FIGS. 3 and 5.

As illustrated in FIGS. 5, 6 he gate driver is not disposed in the second portion of the display area, which is different from the first portion. A pixel circuit disposed in the second portion of the display area does not overlap the gate driver in a plan view of the substrate. The first portion and the second portion are distinguished based on the presence or absence of the gate driver beneath the pixel circuits, rather than by a physical boundary.

The exemplary embodiments of the present disclosure can be further described as follows:

A display device according to an exemplary embodiment of the present disclosure includes a substrate including a display area including a plurality of pixels and a non-display area surrounding the display area, a gate driver disposed in the display area on the substrate and supplying a gate signal, and a plurality of pixel circuits disposed in the plurality of pixels on the gate driver and connected to the gate driver.

The gate driver may include a first transistor, the pixel circuit may include a second transistor, and the second transistor may be disposed on the first transistor.

The active layer of the first transistor and the active layer of the second transistor may be formed of different materials.

The first active layer may include low temperature poly-silicon (LTPS), and the second active layer may include an oxide semiconductor.

The display apparatus may further include a plurality of first gate lines which is disposed on the substrate and supplies a gate signal from the gate driver to the plurality of pixel circuits. The plurality of first gate lines may be disposed on the same layer as the source electrode and the drain electrode of the first transistor.

The display apparatus may further include a plurality of second gate lines disposed between the gate driver and the plurality of pixel circuits. The plurality of second gate lines may connect the plurality of first gate lines and the pixel circuit.

The display apparatus may further include a shielding layer disposed under the plurality of pixel circuits and disposed on the same layer as the plurality of second gate lines.

According to another feature of the present disclosure, the shielding layer may be disposed between the plurality of first gate lines and the plurality of pixel circuits.

According to another feature of the present disclosure, the gate driver may be disposed on at least one side of the display area.

According to another feature of the present disclosure, all first transistors constituting the gate driver may be composed of low-temperature polysilicon transistors, and all second transistors constituting the pixel circuit may be composed of oxide semiconductor transistors.

A display device according to another exemplary embodiment of the present disclosure includes a substrate including a display area and a non-display area surrounding the display area, a gate driver disposed on the substrate in the display area and supplying a gate signal, and a plurality of pixel circuits disposed on the gate driver. The gate driver includes a plurality of first transistors including a first active layer, and the plurality of pixel circuits includes a plurality of second transistors including a second active layer made of a material different from that of the first active layer.

The first active layer may be made of low temperature poly-silicon (LTPS), and the second active layer may be made of an oxide semiconductor.

The display apparatus may further include a plurality of first gate lines which is disposed on the substrate and supplies a gate signal from the gate driver to the plurality of pixels. The plurality of first gate lines may be disposed on the same layer as the source electrode and the drain electrode of the first transistor.

The display apparatus may further include a plurality of second gate lines disposed between the gate driver and the plurality of pixel circuits. The plurality of second gate lines may connect the plurality of first gate lines and the pixel circuit.

The display apparatus may further include a shielding layer disposed under the plurality of pixel circuits and disposed on the same layer as the plurality of second gate lines.

According to another feature of the present disclosure, the shielding layer may be disposed between the plurality of first gate lines and the plurality of pixel circuits.

According to another feature of the present disclosure, the gate driver may be disposed on at least one side of the display area.

Although the exemplary embodiments of the present disclosure have been described in detail with reference to the accompanying drawings, the present disclosure is not limited thereto and may be embodied in various forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described embodiments are illustrative in all aspects and do not limit the present disclosure. The protective scope of the present disclosure should be construed based on the following claims, and all the technical concepts in the equivalent scope thereof should be construed as falling within the scope of the present disclosure.

The various embodiments described above can be combined to provide further embodiments. These and other changes can be made to the embodiments in light of the above-detailed description. In general, in the following claims, the terms used should not be construed to limit the claims to the specific embodiments disclosed in the specification and the claims, but should be construed to include all possible embodiments along with the full scope of equivalents to which such claims are entitled. Accordingly, the claims are not limited by the disclosure.

What is claimed is:

1. A display device, comprising:
a substrate including a display area including a plurality of pixels and a non-display area adjacent to the display area;
a gate driver disposed in the display area on the substrate and configured to supply a gate signal; and
a plurality of pixel circuits disposed in the plurality of pixels on the gate driver and connected to the gate driver.

2. The display device according to claim 1, wherein the gate driver includes a first transistor,
a pixel circuit of the plurality of pixel circuits includes a second transistor, and
the second transistor is disposed on the first transistor.

3. The display device according to claim 2, wherein the first active layer includes low temperature polysilicon (LTPS), and the second active layer includes an oxide semiconductor.

4. The display device according to claim 2, further comprising:
a plurality of first gate lines which is disposed on the substrate and supplies a gate signal from the gate driver to the plurality of pixel circuits,
wherein the plurality of first gate lines is disposed on the same layer as a source electrode and a drain electrode of the first transistor.

5. The display device according to claim 4, further comprising:
a plurality of second gate lines disposed between the gate driver and the plurality of pixel circuits,
wherein the plurality of second gate lines connects the plurality of first gate lines and the pixel circuit.

6. The display device according to claim 5, further comprising:
a shielding layer which is disposed below the plurality of pixel circuits and is disposed on the same layer as the plurality of second gate lines.

7. The display device according to claim 6, wherein the shielding layer is disposed between the plurality of first gate lines and the plurality of pixel circuits.

8. The display device according to claim 1, wherein the gate driver is disposed on at least one side of the display area.

9. The display device according to claim 1, wherein all first transistors constituting the gate driver are composed of low-temperature polysilicon transistors, and
all second transistors constituting each pixel circuit of plurality of pixel circuits are composed of oxide semiconductor transistors.

10. A display device, comprising:
a substrate including a display area and a non display area adjacent to the display area;
a gate driver disposed on the substrate in the display area, the gate driver including a first transistor having a first active layer disposed on the substrate; and
a pixel circuit disposed in the display area, the pixel circuit including a second transistor having a second active layer,
wherein the first active layer and the second active layer are disposed at different vertical levels with at least one insulating layer interposed therebetween,
wherein the pixel circuit overlaps the gate driver in a plan view of the substrate, and
wherein the pixel circuit is connected to the gate driver.

11. The display device according to claim 10, wherein the first active layer includes low temperature polysilicon and the second active layer includes an oxide semiconductor.

12. The display device according to claim 10, further comprising a gate line configured to transmit a gate signal from the gate driver to the pixel circuit,wherein the gate line is disposed at a vertical level between the first active layer and the second active layer.

13. The display device according to claim 12, wherein the gate line overlaps the second transistor in a plan view of the substrate.

14. The display device according to claim 10, further comprising a shielding layer disposed between the gate driver and the pixel circuit.

15. The display device according to claim 14, further comprising a gate line configured to transmit a gate signal from the gate driver to the pixel circuit,
wherein the shielding layer is disposed between the gate line and the second transistor.

16. The display device according to claim 15, wherein the shielding layer is disposed on a same layer as the gate line.

17. The display device according to claim 14, wherein the shielding layer overlaps the second transistor in a plan view of the substrate.

18. The display device according to claim 10, wherein the gate driver is disposed along only one side of the display area and the pixel circuit overlaps the gate driver only along that side.

19. The display device according to claim 10, wherein the gate driver is disposed in a first portion of the display area, and a pixel circuit disposed in the first portion of the display area overlaps the gate driver in a plan view of the substrate.

20. The display device according to claim 19, wherein the gate driver is not disposed in a second portion of the display area different from the first portion, and a pixel circuit disposed in the second portion of the display area does not overlap the gate driver in a plan view of the substrate.
